(19) United States
(12) Patent Application Publication
(10) Pub. No.: US 2014/0014975 A1
(43) Pub. Date: Jan. 16, 2014

(54) SEMICONDUCTOR CHIP INCLUDING HEAT RADIATION MEMBER, AND DISPLAY MODULE

(71) Applicant: SAMSUNG ELECTRONICS CO., LTD., Suwon-Si (KR)

(72) Inventors: Jong-kon BAE, Seoul (KR); Won-sik KANG, Seoul (KR); Jae-hyuck WOO, Osan-si (KR); Sung-ki KIM, Seoul (KR); Yang-hyo KIM, Hwaseong-si (KR); Do-kyung KIM, Yongin-si (KR)

(73) Assignee: Samsung Electronics Co., Ltd., Suwon-Si (KR)

(21) Appl. No.: 13/837,757

(22) Filed: Mar. 15, 2013

(30) Foreign Application Priority Data
Jul. 12, 2012 (KR) 10-2012-0076282

(51) Int. Cl. H01L 23/367; H01L 33/64

(52) U.S. Cl. CPC H01L 23/3677; H01L 33/642
USPC 257/79; 257/712

(57) ABSTRACT

A semiconductor chip includes a circuit region having an integrated semiconductor circuit on a semiconductor substrate, and a heat radiation member on at least a portion of a scribe lane region configured to at least partially surround the circuit region, the heat radiation member including a plurality of heat radiation fins that extend in a direction orthogonal to an upper surface of the semiconductor substrate.

### CROSS-REFERENCE TO RELATED APPLICATIONS

This application claims the benefit of Korean Patent Application No. 10-2012-0076282, filed on Jul. 12, 2012, in the Korean Intellectual Property Office, the disclosure of which is incorporated herein in its entirety by reference.

### BACKGROUND

Some example embodiments relate to a semiconductor chip and a display module, and more particularly, to a semiconductor chip including a heat radiation member, and a display module.

Since applications of electronic products provide various functions at higher speeds, the processing speed of circuits integrated on a semiconductor chip is increased, and thus, power consumption of the semiconductor chip is also increased. Also, due to a high-resolution screen of a display module mounted on a mobile electronic device such as a smart phone, power consumption of a display driving chip is increased. If power consumption of a semiconductor chip is increased, a heat generation rate is also increased. Accordingly, a semiconductor chip has to efficiently radiate heat generated when circuits operate to the outside of the semiconductor chip.

### SUMMARY

Some example embodiments provide a semiconductor chip capable of efficiently radiating heat generated by the semiconductor chip to the outside of the semiconductor chip.

According to an example embodiment, a semiconductor chip includes a circuit region on a semiconductor substrate, the circuit region having an integrated semiconductor circuit, and a heat radiation member on at least a portion of a scribe lane region configured to at least partially surround the circuit region, the heat radiation member including a plurality of heat radiation fins that extend in a direction orthogonal to an upper surface of the semiconductor substrate.

The plurality of heat radiation fins may have one of a plate and pole shape. The plurality of heat radiation fins may have different heights. The plurality of heat radiation fins may include a plurality of plate-shaped heat radiation fins sequentially spaced apart from each other on the upper surface of the semiconductor substrate in a direction that is one of perpendicular and parallel to a side surface of the semiconductor chip. The heat radiation member may include a plurality of pole-shaped heat radiation fins sequentially spaced apart from each other on the upper surface of the semiconductor substrate in a direction that is one of perpendicular and parallel to a side surface of the semiconductor chip.

The heat radiation member may further include a body on the semiconductor substrate, and the body may be connected to the plurality of heat radiation fins. The heat radiation member may be connected to one of a power supply voltage wiring and a ground voltage wiring of the semiconductor circuit on the circuit region. The heat radiation member may be exposed by an opening.

The heat radiation member may include a plurality of metal layers and a plurality of vias that are alternately stacked. A plurality of wiring layers may be on the circuit region. At least one wiring layer of the plurality of wiring layers may include a wiring region having wirings of the integrated semiconductor circuit formed thereon and a dummy portion on a region other than the wiring region. The dummy portion may be integrally formed on a region separate from the wiring region.

According to an example embodiment, a display module includes a display panel including a plurality of pixel cells, a display driving chip configured to drive the plurality of pixel cells, the display driving chip including a scribe lane region, a heat radiation member on at least a portion of the scribe lane region of the display driving chip, and a printed circuit board (PCB) having the display driving chip mounted thereon, the PCB including wirings configured to electrically connect the display driving chip and the display panel.

The PCB may include a heat radiation plate formed separate from a region where the display driving chip is mounted and a region where the wirings are formed. A side surface of the heat radiation plate may be configured to contact a side surface of the display driving chip. The heat radiation plate may be configured to electrically connect to one of a power supply voltage pad and a ground voltage pad of the display driving chip. The PCB may be a glass substrate.

According to an example embodiment, a semiconductor chip includes a semiconductor substrate defining a groove that at least partially surrounds an integrated circuit region, and a heat radiation member in at least a portion of the groove, the heat radiation member including a conductive material.

The conductive material may include a metallic material. The metal of the metallic material may be one of copper (Cu), aluminum (Al), and tungsten (W). The heat radiation member may include a plurality of heat radiation fins that extend in a direction orthogonal to an upper surface of the semiconductor substrate. The plurality of heat radiation fins may be exposed.

### BRIEF DESCRIPTION OF THE DRAWINGS

Example embodiments will be more clearly understood from the following detailed description taken in conjunction with the accompanying drawings in which:

FIG. 1 is a plan view of a semiconductor chip according to an example embodiment;

FIG. 2 is a cross-sectional view of the semiconductor chip illustrated in FIG. 1, according to an example embodiment;

FIGS. 3A and 3B are perspective views of a heat radiation member illustrated in FIG. 2, according to example embodiments;

FIGS. 4A and 4B are cross-sectional views of the heat radiation member illustrated in FIG. 2, according to example embodiments;

FIGS. 5A through 5F are plan views of the heat radiation member illustrated in FIG. 2, according to example embodiments;

FIGS. 6A and 6B are cross-sectional views of the heat radiation member illustrated in FIG. 2, based on various manufacturing processes, according to example embodiments;

FIG. 7 is a cross-sectional view of the semiconductor chip illustrated in FIG. 1, according to another example embodiment;

FIG. 8 is a cross-sectional view of the semiconductor chip illustrated in FIG. 1, according to another example embodiment;

FIGS. 9A and 9B are plan views of a wiring layer of a semiconductor chip, according to example embodiments;

FIGS. 10A through 10C illustrate a semiconductor chip according to another example embodiment;

FIG. 11 is a schematic view of a display module according to an example embodiment;

FIG. 12 is a perspective view of a display apparatus according to an example embodiment; and

FIG. 13 is a schematic view showing various electronic products including the display apparatus illustrated in FIG. 12, according to example embodiments.

### DETAILED DESCRIPTION

The inventive concepts will now be described more fully with reference to the accompanying drawings, in which example embodiments of the inventive concepts are shown. The inventive concepts may, however, be embodied in many different forms and should not be construed as being limited to the embodiments set forth herein; rather, these embodiments are provided so that this disclosure will be thorough and complete, and will fully convey the concept of the inventive concepts to one of ordinary skill in the art. It should be understood, however, that there is no intent to limit example embodiments of the inventive concepts to the particular forms disclosed, but conversely, example embodiments of the inventive concepts are to cover all modifications, equivalents, and alternatives falling within the spirit and scope of the inventive concepts. In the drawings, like reference numerals denote like elements and the sizes or thicknesses of elements may be exaggerated for clarity of explanation.

The terminology used herein is for the purpose of describing particular embodiments and is not intended to limit the inventive concepts. As used herein, the singular forms “a”, “an”, and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Unless defined differently, all terms used in the description including technical and scientific terms have the same meaning as generally understood by one of ordinary skill in the art. Terms as defined in a commonly used dictionary should be construed as having the same meaning as in an associated technical context, and unless defined in the description, the terms are not ideally or excessively construed as having formal meaning.

As used herein, the term “and/or” includes any and all combinations of one or more of the associated listed items.

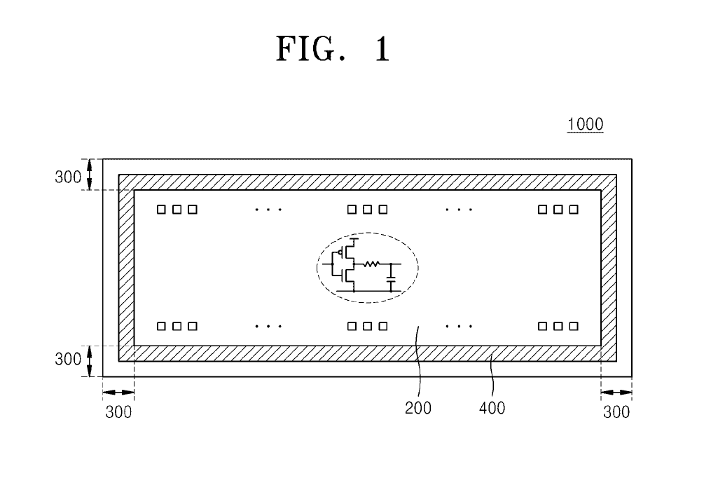

FIG. 1 is a plan view of a semiconductor chip 1000 according to an example embodiment. Referring to FIG. 1, the semiconductor chip 1000 may include a circuit region 200 and a heat radiation member 400. The circuit region 200 has an integrated semiconductor circuit. On the circuit region 200, a plurality of semiconductor devices for forming semiconductor circuits, for example, transistors and/or capacitors, may be formed. Also, input pads for transferring voltages or signals applied from an external device to the semiconductor devices, and output pads for outputting internally generated voltages or signals to the external device may be formed. Furthermore, wirings for applying voltages or signals to the semiconductor devices may be formed.

The heat radiation member 400 is formed of a material having a relatively high thermal conductivity, and radiates heat generated when integrated circuits operate to the outside of the semiconductor chip 1000. In this case, the heat radiation member 400 is formed on at least a portion of a groove (or, alternatively scribe lane region) 300. The groove (or, alternatively scribe lane region) 300 refers to spaces required to cut a wafer into a plurality of semiconductor chips. Since the groove (or, alternatively scribe lane region) 300 refers to spaces between the circuit regions 200 of adjacent semiconductor chips on the wafer, in a semiconductor chip, the groove (or, alternatively scribe lane region) 300 refers to spaces adjacent to four sides of the semiconductor chip 1000.

In general, the groove (or, alternatively scribe lane region) 300 has spaces greater than those physically required to cut the wafer. Since particles may fall on portions near edges of the semiconductor chip 1000 when the wafer is cut, if the particles are placed on the circuit region 200, the semiconductor chip 1000 may malfunction. Therefore, the groove (or, alternatively scribe lane region) 300 may be formed to have a width greater than that actually required to cut the wafer such that particles generated when the wafer is cut may not fall on the circuit region 200. As such, the groove (or, alternatively scribe lane region) 300 includes extra spaces remaining on the semiconductor chip 1000 after the wafer is cut. The semiconductor chip 1000 may include the heat radiation member 400 formed on the extra spaces of the groove (or, alternatively scribe lane region) 300.

As illustrated in FIG. 1, the heat radiation member 400 may be located adjacent to the circuit region 200, and may be formed on the groove (or, alternatively scribe lane region) 300 located on four sides of the semiconductor chip 1000. However, the current embodiment is not limited thereto. The heat radiation member 400 may be formed on the groove (or, alternatively scribe lane region) 300 corresponding to one side or two facing sides of the semiconductor chip 1000. Also, a circuit for performing a wafer-level process test and monitoring may be formed on a portion of the groove (or, alternatively scribe lane region) 300, and the heat radiation member 400 may be formed on the other portion of the groove (or, alternatively scribe lane region) 300.

As described above, since the semiconductor chip 1000 includes the heat radiation member 400, heat generated when integrated circuits operate may be efficiently radiated to the outside of the semiconductor chip 1000. Also, since the heat radiation member 400 is formed on the groove (or, alternatively scribe lane region) 300, the heat radiation member 400 may be formed without increasing a chip size.

Although the semiconductor chip 1000 is illustrated as a display driving chip of which long sides are much longer than its short sides in FIG. 1, the current embodiment is not limited thereto. The semiconductor chip 1000 may have various forms. Also, the semiconductor chip 1000 may include various types of circuits.

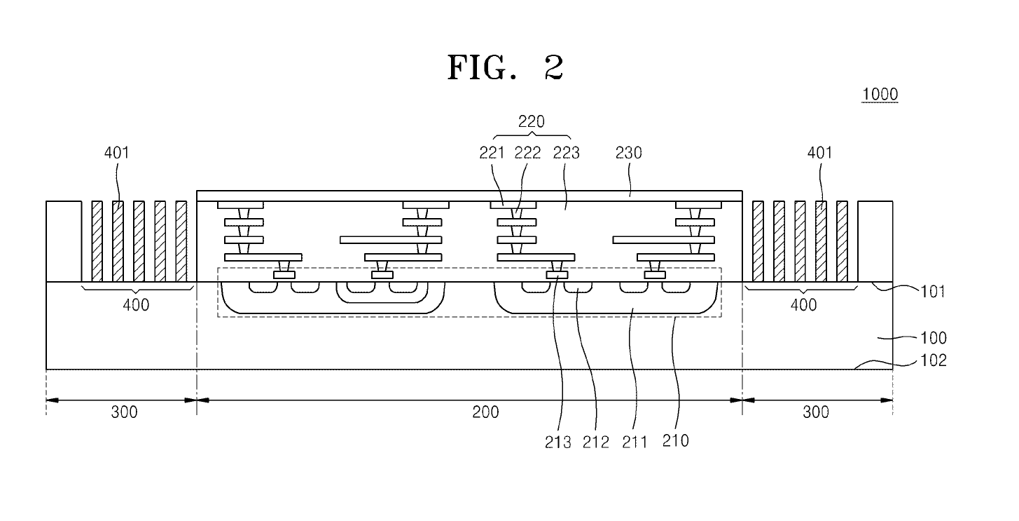

FIG. 2 is a cross-sectional view of the semiconductor chip 1000 illustrated in FIG. 1, according to an example embodiment. Referring to FIG. 2, the semiconductor chip 1000 may include the circuit region 200 and the groove (or, alternatively scribe lane region) 300. The circuit region 200 is located at the center of the semiconductor chip 1000, and the groove (or, alternatively scribe lane region) 300 is located outside the circuit region 200. A semiconductor device portion 210, a wiring portion 220, and a passivation layer 230 may be formed on the circuit region 200.

As described above in relation to FIG. 1, semiconductor devices for forming integrated circuits, input/output pads, and wirings may be formed on the circuit region 200. In this case, the semiconductor devices may be formed on the semiconductor device portion 210, and the wirings may be formed on the wiring portion 220. Also, although not shown in FIG. 2, the input/output pads may be formed on the wiring portion 220.

The semiconductor device portion 210 may include well regions 211, active regions 212, and gates 213, and may be formed on a semiconductor substrate 100.

The semiconductor substrate 100 may be formed as a semiconductor wafer having a first surface 101 and a second surface 102 facing the first surface 101. The semiconductor substrate 100 may include a silicon (Si) material. Also, a semiconductor element such as germanium (Ge), or a compound semiconductor such as silicon carbide (SiC), gallium arsenide (GaAs), indium arsenide (InAs), or indium phosphide (InP) may be included.

The well regions 211 may be formed by doping the first surface 101 of the semiconductor substrate 100 with an impurity, the active regions 212 of the well regions 211 may be doped with an impurity having a type and density different from those of the impurity doped on the well regions 211, and the gates 213 may be formed on the active regions 212 by using polysilicon, thereby forming semiconductor devices such as transistors, capacitors, or diodes. In some cases, the semiconductor device portion 210 may be formed in the semiconductor substrate 100.

The wiring portion 220 may include wirings 221, vias 222, and an insulating material 223. The wirings 221 may be connected to the semiconductor devices formed on the semiconductor device portion 210 so as to form circuits, or may be used to electrically connect internal circuits to external devices. The wirings 221 may be formed of a conductive material. For example, the wirings 221 may be formed of a metallic material such as copper (Cu), aluminum (Al), or tungsten (W), or a mixed material including the metallic material. The wirings 221 may be formed as a plurality of wiring layers at different levels, and two or more same-level or different-level wirings 221 may be spaced apart from each other by the insulating material 223. The insulating material 223 may include a non-conductive material such as silicon oxide (SiO₂).

The different-level wirings 221 may be connected to each other by the vias 222. Also, the wirings 221 may be connected to the input/output pads or the semiconductor devices through the vias 222. The vias 222 may be formed of a conductive material such as Cu, Al, or W, or a mixed material including the conductive material. The vias 222 may be formed of a material the same as the material used to form the wirings 221. Although the wirings 221 and the vias 222 are respectively formed as layers of two levels in FIG. 2, the number of levels of the wirings 221 and the vias 222 included in the wiring portion 220 may vary according to a manufacturing process.

The passivation layer 230 may be formed on the wiring portion 220. The passivation layer 230 may protect the semiconductor chip 1000 from moisture or impurities. The passivation layer 230 may be formed as an oxide or nitride layer, or a double layer of oxide and nitride layers. Also, the passivation layer 230 may be formed as an oxide layer, e.g., an SiO₂ layer, by using a high density plasma chemical vapor deposition (HDP-CVD) process.

The heat radiation member 400 may be formed on at least a portion of the groove (or, alternatively scribe lane region) 300. The heat radiation member 400 may include a plurality of heat radiation fins 401. The heat radiation fins 401 may extend in a direction perpendicular to the first surface 101 of the semiconductor substrate 100 and may be spaced apart from each other. According to the current embodiment, the heat radiation fins 401 may be spaced apart from each other by a given (or alternatively, predetermined) distance. For example, the given (or alternatively, predetermined) distance may be a minimum distance allowed by design rules of a manufacturing process of the semiconductor chip 1000. If the heat radiation fins 401 are disposed as close as possible to each other and thus a large number of heat radiation fins 401 are formed, a heat radiation area may be increased.

Also, an opening may be formed above the heat radiation member 400 and thus the heat radiation member 400 may be exposed externally. As described above, the passivation layer 230 is formed on the wiring portion 220 so as to protect the semiconductor chip 1000. However, the passivation layer 230 may not be formed on the heat radiation member 400 so as to form the opening. Since the opening exposes upper and side surfaces of the heat radiation fins 401 to air, the heat radiation member 400 may directly radiate heat generated from the inside of the semiconductor chip 1000 to the outside of the semiconductor chip 1000.

In addition, the heat radiation member 400 may be formed of a material having a relatively high thermal conductivity. For example, the heat radiation member 400 may be formed of a metallic material such as Al, Cu, or W, or a mixed material including the metallic material. If the heat radiation member 400 is formed simultaneously with the semiconductor device portion 210 and the wiring portion 220, the heat radiation member 400 may be formed of the same material as the material used to form the wirings 221, the vias 222, and/or the gates 213. However, the current embodiment is not limited thereto. The heat radiation member 400 may be separately formed after the semiconductor device portion 210 and the wiring portion 220 are formed. In this case, the heat radiation member 400 may be formed of a material different from the material used to form the wirings 221, the vias 222, and/or the gates 213. Detailed descriptions thereof will be provided below with reference to FIGS. 6A and 6B.

As described above, the heat radiation member 400 is formed of a metallic material having a high thermal conductivity, and includes the heat radiation fins 401 of which sides and upper surfaces are exposed to air so as to have a relatively large area contacting air. Accordingly, the heat radiation member 400 may efficiently radiate heat generated from the inside of the semiconductor chip 1000 to the outside of the semiconductor chip 1000.

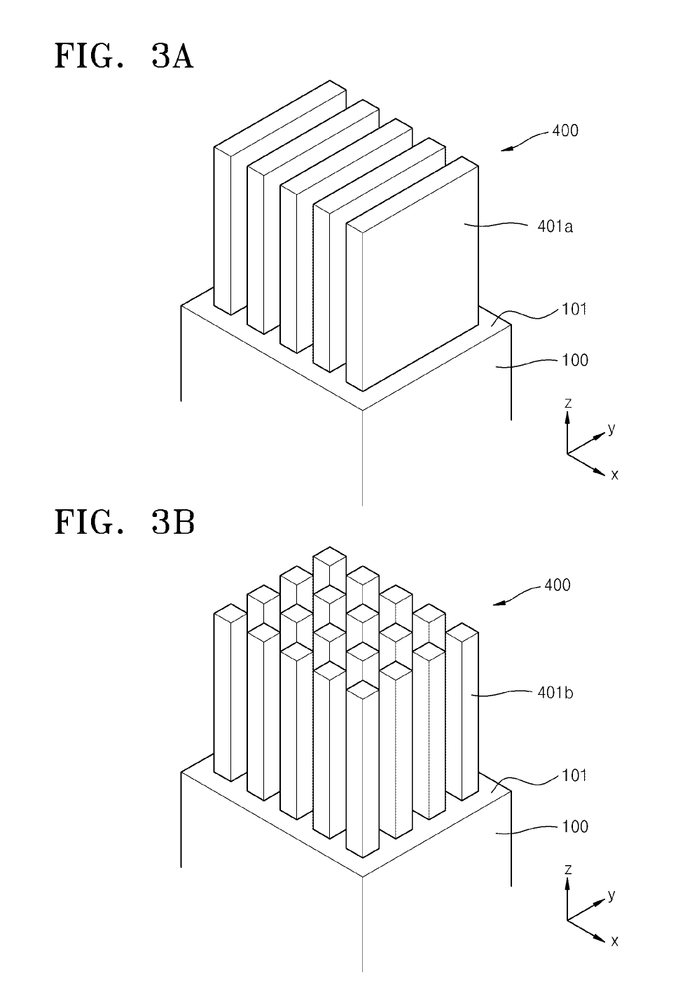

The heat radiation member 400 illustrated in FIG. 2 will now be described in detail with reference to FIGS. 3A through 6B.

FIGS. 3A and 3B are perspective views of the heat radiation member 400 illustrated in FIG. 2, according to example embodiments. FIG. 3A illustrates plate-shaped heat radiation fins 401a, and FIG. 3B illustrates pole-shaped heat radiation fins 401b.

Referring to FIG. 3A, the heat radiation member 400 may include a plurality of plate-shaped heat radiation fins 401a. The plate-shaped heat radiation fins 401a may extend in a first direction (z-axis direction) perpendicular to the first surface 101 of the semiconductor substrate 100, and a second direction (y-axis direction) or a third direction (x-axis direction) perpendicular to the first direction. The plate-shaped heat radiation fins 401a may be sequentially spaced apart from each other in a direction other than the directions in which the plate-shaped heat radiation fins 401a extend. For example, as illustrated in FIG. 3A, the plate-shaped heat radiation fins 401a may extend in the first direction (z-axis direction) and the second direction (y-axis direction), and may be sequentially spaced apart from each other in the third direction (x-axis direction). According to another example embodiment, the plate-shaped heat radiation fins 401a may extend in the first direction (z-axis direction) and the third direction (x-axis direction), and may be sequentially spaced apart from each other in the second direction (y-axis direction).

Referring to FIG. 3B, the heat radiation member 400 may include the pole-shaped heat radiation fins 401b. The pole-shaped heat radiation fins 401b may extend in the first direction (z-axis direction) perpendicular to the first surface 101 of the semiconductor substrate 100. The pole-shaped heat radiation fins 401b may be sequentially spaced apart from each other in the second direction (y-axis direction) and the third direction (x-axis direction) perpendicular to the first direction. Although the pole-shaped heat radiation fins 401b have a square pole shape in FIG. 3B, the current embodiment is not limited thereto. The pole-shaped heat radiation fins 401b may have a circular pole shape (i.e., a cylindrical shape).

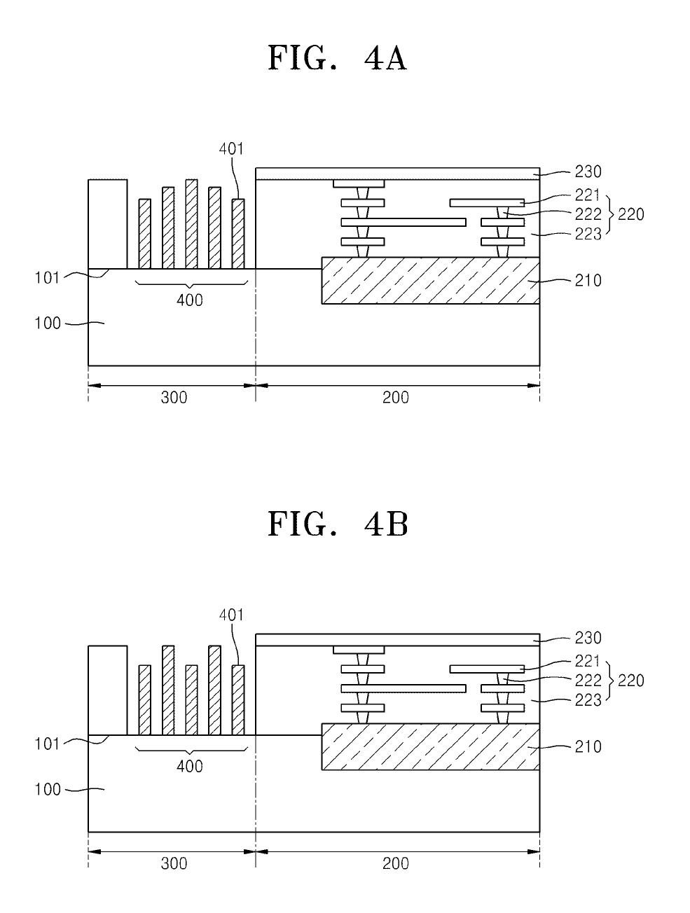

Meanwhile, although the plate-shaped or pole-shaped heat radiation fins 401a or 401b have the same height (i.e., the same length in the first direction (z-axis direction) perpendicular to the first surface 101 of the semiconductor substrate 100 in FIG. 3A or 3B, the current embodiment is not limited thereto. The plate-shaped or pole-shaped heat radiation fins 401a or 401b may have various heights. For example, as illustrated in FIG. 4A , the heat radiation fins 401 may have heights that gradually reduce from the center of the heat radiation member 400 toward edges of the heat radiation member 400 close to the circuit region 200 and side surfaces of the semiconductor chip 1000. Also, as illustrated in FIG. 4B, adjacent heat radiation fins 401 may have different heights. Furthermore, the height of the heat radiation fins 401 may be variously changed to efficiently radiate heat.

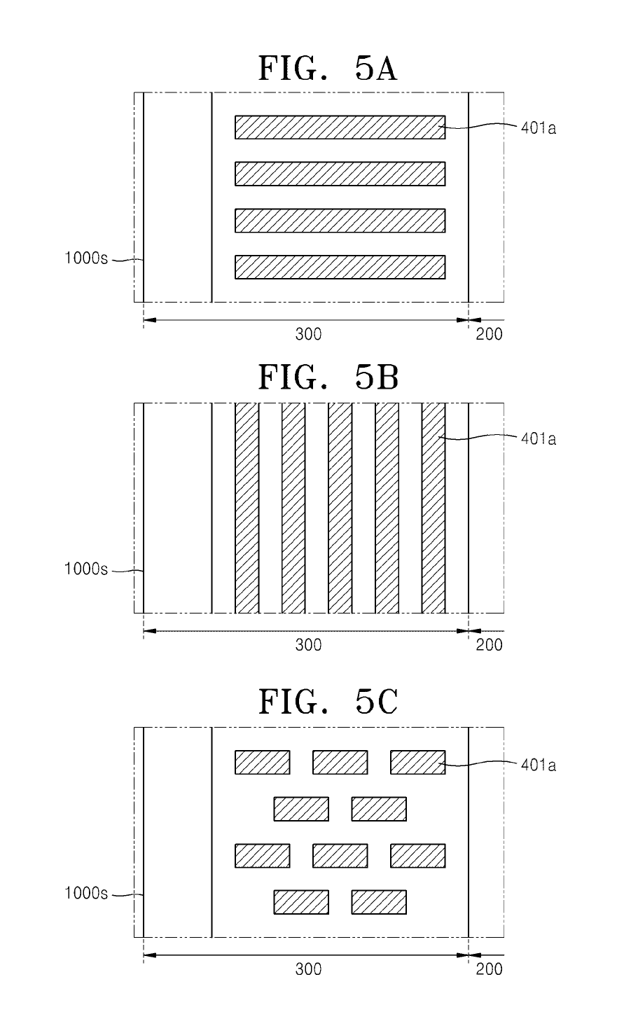

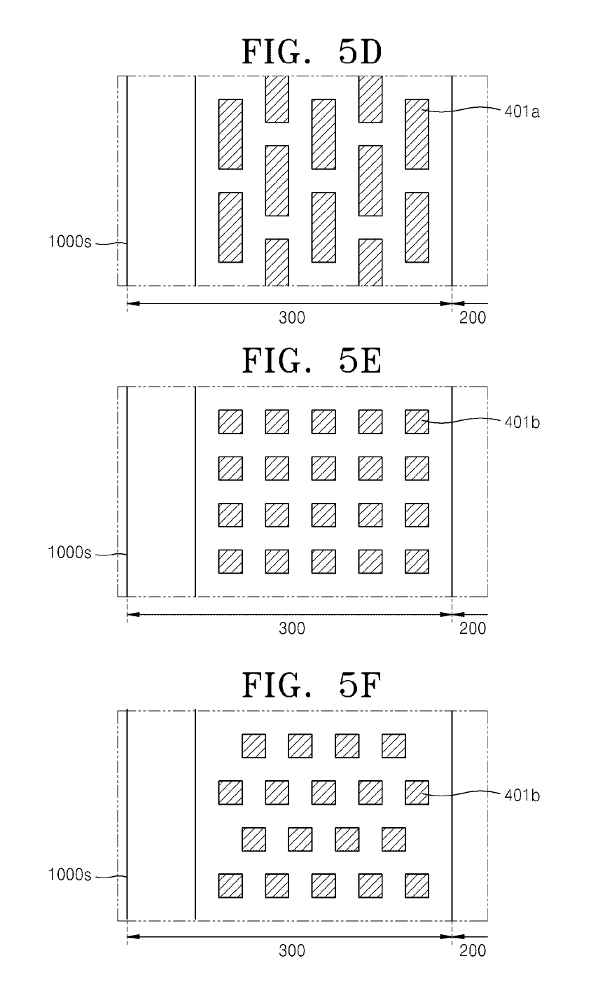

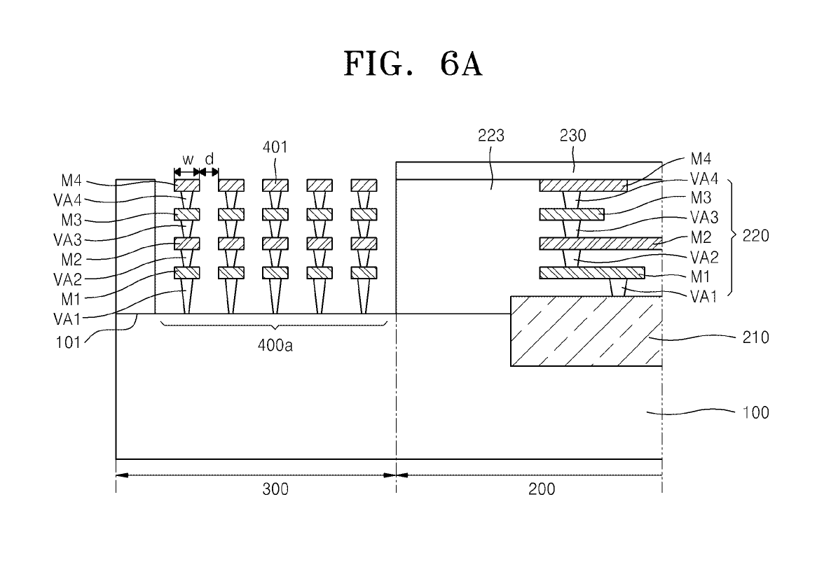

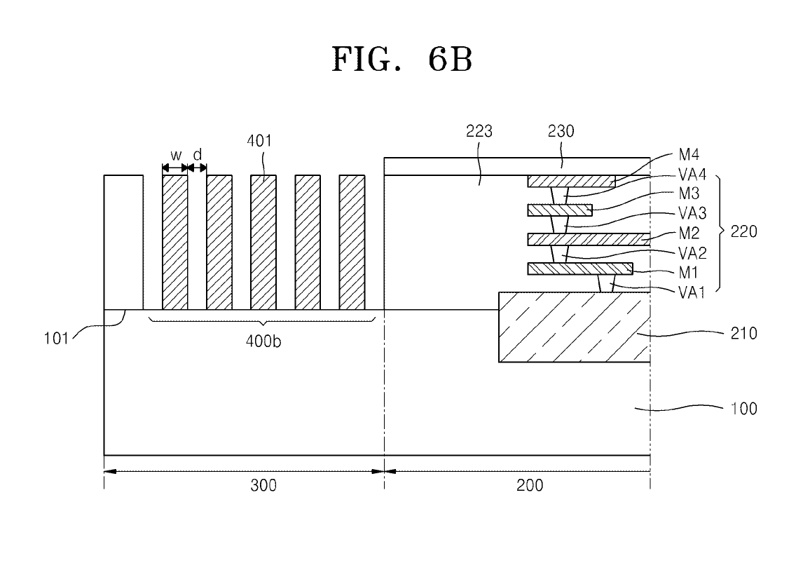

FIGS. 5A through 5F are plan views of the heat radiation member 400 illustrated in FIG. 2, according to example embodiments. For convenience of explanation, the groove (or, alternatively scribe lane region) 300 including the heat radiation member 400, and a portion of the circuit region 200 in the plan view of the semiconductor chip 1000 illustrated in FIG. 1 are magnified here.

FIGS. 5A through 5D are plan views of the heat radiation member 400 including the plate-shaped heat radiation fins 401a illustrated in FIG. 3A, and FIGS. 5E and 5F are plan views of the heat radiation member 400 including the pole-shaped heat radiation fins 401b illustrated in FIG. 3B.

Referring to FIG. 5A, the plate-shaped heat radiation fins 401a may be disposed in a direction perpendicular to one side surface 1000s of the semiconductor chip 1000, and may be sequentially spaced apart from each other in parallel. Also, referring to FIG. 5B, the plate-shaped heat radiation fins 401a may be disposed in a direction parallel to the side surface 1000s of the semiconductor chip 1000, and may be sequentially spaced apart from each other in parallel to each other.

Referring to FIG. 5C, the plate-shaped heat radiation fins 401a may be sequentially spaced apart from each other in a direction perpendicular to the side surface 1000s of the semiconductor chip 1000, and may also be sequentially spaced apart from each other in parallel. In this case, the plate-shaped heat radiation fins 401a disposed in parallel to each other may be diagonally aligned with respect to the side surface 1000s of the semiconductor chip 1000. Also, referring to FIG. 5D, the plate-shaped heat radiation fins 401a may be sequentially spaced apart from each other in a direction parallel to the side surface 1000s of the semiconductor chip 1000, and may also be sequentially spaced apart from each other in parallel.

As illustrated in FIGS. 5A through 5D, if the plate-shaped heat radiation fins 401a are disposed in a direction perpendicular or parallel to the side surface 1000s of the semiconductor chip 1000, the heat radiation member 400 may be formed in a stripe pattern.

Referring to FIG. 5E, the pole-shaped heat radiation fins 401b may be spaced apart from each other in directions perpendicular and parallel to the side surface 1000s of the semiconductor chip 1000. Also, referring to FIG. 5F, the pole-shaped heat radiation fins 401b may be spaced apart from each other in directions perpendicular, parallel, and diagonal to the side surface 1000s of the semiconductor chip 1000. As illustrated in FIGS. 5E and 5F, since the pole-shaped heat radiation fins 401b may be spaced from each other, the heat radiation member 400 may be formed in a grid pattern.

As described above in relation to FIGS. 5A through 5F, the heat radiation member 400 may be formed in various patterns. However, the current embodiment is not limited thereto. The heat radiation member 400 may be formed in various patterns in consideration of heat radiation efficiency.

FIGS. 6A and 6B are cross-sectional views of the heat radiation member 400 illustrated in FIG. 2, based on various manufacturing processes, according to example embodiments.

FIG. 6A illustrates a heat radiation member 400a formed simultaneously with the semiconductor device portion 210 and the wiring portion 220, and FIG. 6B illustrates a heat radiation member 400b separately formed after the semiconductor device portion 210 and the wiring portion 220 are formed.

Referring to FIG. 6A, the semiconductor device portion 210 and the wiring portion 220 are formed on the circuit region 200, and the heat radiation member 4001 is formed on a partial region of the scribe lane 300. The semiconductor device portion 210 and the wiring portion 220 are formed on an upper region of the semiconductor substrate 100 adjacent to the first surface 101 of the semiconductor substrate 100. The semiconductor device portion 210 is formed on the upper region of the semiconductor substrate 100, and then first through fourth vias VA1 through VA4 and first through fourth metal wirings M1 through M4 are alternately stacked on the semiconductor device portion 210 so as to form the wiring portion 220. As described above in relation to FIG. 2, the first through fourth vias VA1 through VA4 and the first through fourth metal wirings M1 through M4 may be formed of a metallic material.

The insulating material 223 may be filled between the first through fourth vias VA1 through VA4 and the first through fourth metal wirings M1 through M4 such that the first through fourth metal wirings M1 through M4 may be spaced apart from each other. Vias and metal wirings are respectively formed as layers of four levels in FIG. 6A. However, the current embodiment is not limited thereto and the number of levels of vias and metal wirings may vary according to a manufacturing process.

The heat radiation member 400a may be formed simultaneously with the semiconductor device portion 210 and the wiring portion 220. As illustrated in FIG. 6A, the heat radiation member 400 may be formed by alternately stacking the first through fourth vias VA1 through VA4 and the first through fourth metal wirings M1 through M4. Accordingly, the heat radiation member 400a may be formed of the metallic material used to form the wiring portion 220. Also, a width w and a distance d between the heat radiation fins 401 may be a minimum width and distance allowed by design rules of a manufacturing process of the wiring portion 220. In addition, an insulating material may be filled between the heat radiation fins 401 and may be removed by performing a photo etching process after the wiring portion 220 or the passivation layer 230 is formed.

Although the heat radiation member 400a, like the wiring portion 220, includes the first through fourth vias VA1 through VA4 and the first through fourth metal wirings M1 through M4 in FIG. 6A, the current embodiment is not limited thereto. The heat radiation member 400a may include some lower vias and metal wirings, for example, the first through third vias VA1 through VA3 and the first through third metal wirings M1 through M3. Also, the heat radiation member 400a may include some upper vias and metal wirings, for example, the second through fourth vias VA2 through VA4 and the second through fourth metal wirings M2 through M4. Furthermore, the heat radiation member 400a may be formed of a metallic material used to form the first through fourth vias VA1 through VA4, the first through fourth metal wirings M1 through M4, and polysilicon used to form the semiconductor device portion 210.

The heat radiation member 400b formed separately from the semiconductor device portion 210 and the wiring portion 220 will now be described.

FIG. 6B illustrates the heat radiation member 400b formed separately from the semiconductor device portion 210 and the wiring portion 220. For example, the heat radiation member 400b may be separately formed after the semiconductor device portion 210 and the wiring portion 220 are formed, or the semiconductor device portion 210, the wiring portion 220, and the passivation layer 230 are formed.

When the semiconductor device portion 210 and the wiring portion 220 are formed on the circuit region 200, a partial region of the scribe lane 300, i.e., a region on which the heat radiation member 400b is formed, may be filled with an insulating material. After that, a plurality of recesses may be formed by performing, for example, a photo etching process, a heat radiation material may be filled in the recesses, and thus the heat radiation member 400b may be formed as illustrated in FIG. 6B. In this case, the width w and the distance d between the heat radiation fins 401 may be a minimum width and distance allowed by design rules of a manufacturing process of the heat radiation member 400b.

The heat radiation member 400b may be formed of a conductive material. For example, the heat radiation member 400b may be formed of a metallic material such as W, Al, or Cu, or a mixed material including the metallic material. In addition, since the heat radiation member 400b is formed separately from the semiconductor device portion 210 and the wiring portion 220, the heat radiation member 400b may be formed of a material different from the material used to form the semiconductor device portion 210 and the wiring portion 220. However, the current embodiment is not limited thereto. Since the semiconductor device portion 210 and the wiring portion 220 may also be formed of a metallic material, the heat radiation member 400b may be formed of a material the same as the material used to form the semiconductor device portion 210 and the wiring portion 220.

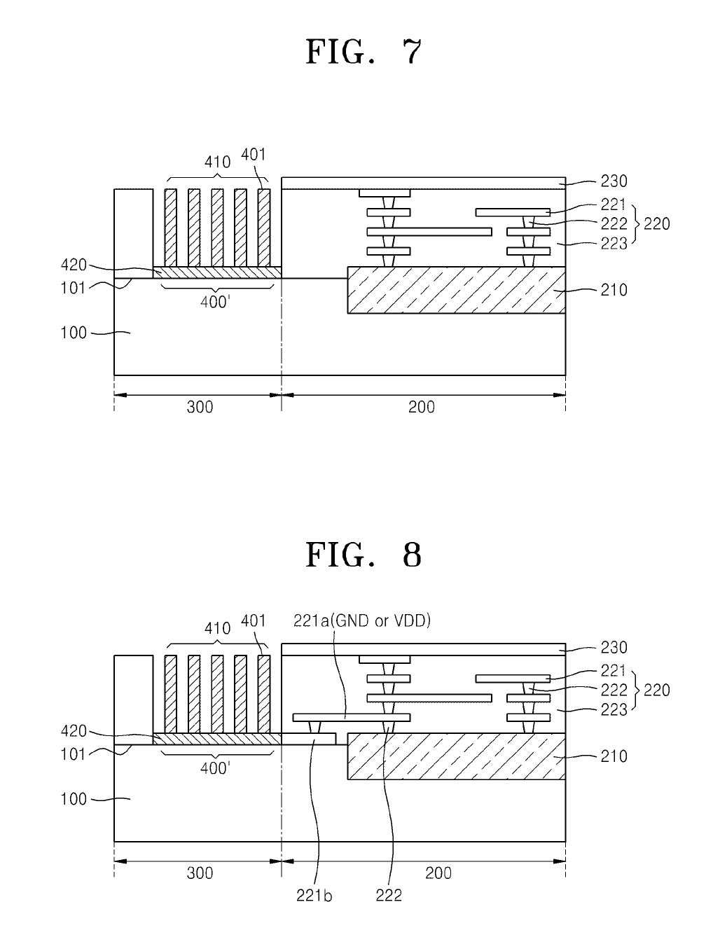

FIG. 7 is a cross-sectional view of the semiconductor chip 1000 illustrated in FIG. 1, according to another example embodiment. Referring to FIG. 7, the semiconductor chip 1000 may include the circuit region 200 and the groove (or, alternatively scribe lane region) 300. The semiconductor device portion 210, the wiring portion 220, and the passivation layer 230 may be formed on the circuit region 200, and a heat radiation member 400′ may be formed on at least a portion of the groove (or, alternatively scribe lane region) 300.

Compared to the semiconductor chip 1000 illustrated in FIG. 2, the difference is the structure of the heat radiation member 400′ included in the semiconductor chip 1000. Accordingly, the semiconductor substrate 100, the semiconductor device portion 210, and the wiring portion 220 are the same as those illustrated in FIG. 2, and thus detailed descriptions thereof are not provided here.

The heat radiation member 400′ may include a heat radiation fin portion 410 including the heat radiation fins 401, and a body 420. The body 420 is formed on and in parallel to the first surface 101 of the semiconductor substrate 100, and is connected to the heat radiation fins 401. The heat radiation fins 401 may extend in a direction orthogonal to the first surface 101 of the semiconductor substrate 100, and may be spaced apart from each other on the body 420. The heat radiation fins 401 and the body 420 may be formed of a metallic material such as Al, Cu, or W. However, the current embodiment is not limited thereto and the heat radiation fins 401 and the body 420 may be formed of another metallic material having a relatively high thermal conductivity. Also, the heat radiation fins 401 may be formed in a plate or pole shape, as illustrated in FIG. 3A or 3B, and a pattern of the heat radiation member 400′ formed by the heat radiation fins 401 may be one of the patterns illustrated in FIGS. 5A through 5F.

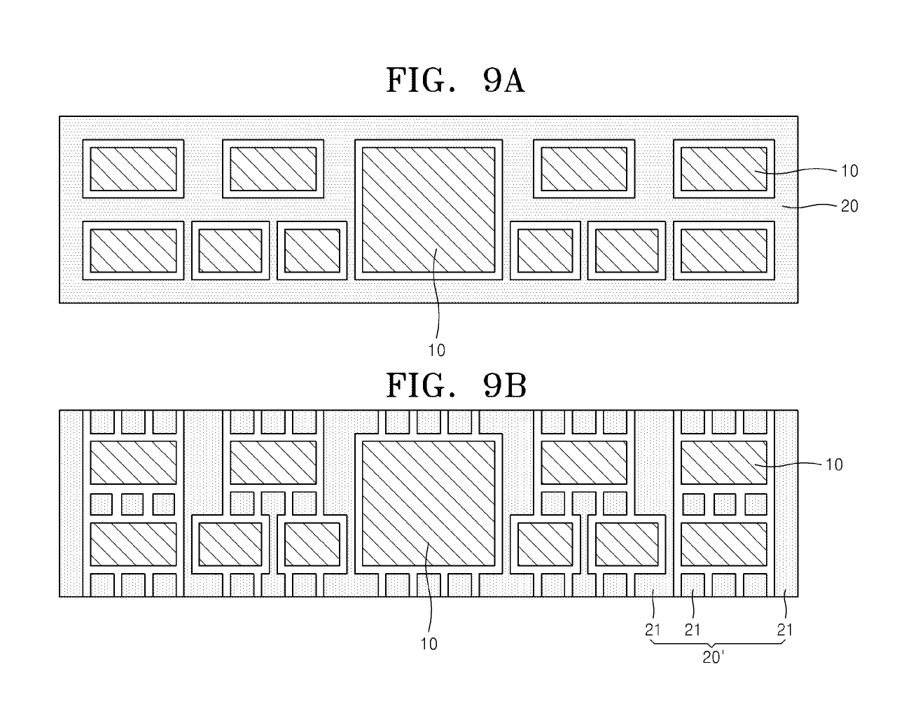

FIG. 8 is a cross-sectional view of the semiconductor chip 1000 illustrated in FIG. 1, according to another example embodiment.

Referring to FIG. 8, the semiconductor chip 1000 may include the circuit region 200 and the groove (or, alternatively scribe lane region) 300. The semiconductor device portion 210, the wiring portion 220, and the passivation layer 230 may be formed on the circuit region 200, and the heat radiation member 400′ may be formed on at least a portion of the groove (or, alternatively scribe lane region) 300. The semiconductor substrate 100, the semiconductor device portion 210, and the wiring portion 220 are the same as those illustrated in FIG. 2, and thus detailed descriptions thereof are not provided here.

The heat radiation member 400′ may be the same as that illustrated in FIG. 7. The heat radiation member 400′ may include the heat radiation fin portion 410 including the heat radiation fins 401, and the body 420.

In FIG. 8, the heat radiation member 400′ may be connected to a wiring 221a of a ground voltage GND or a power supply voltage VDD. The wiring 221a of the ground voltage GND or the power supply voltage VDD transfers the ground voltage GND or the power supply voltage VDD applied through an input pad from an external device to circuit devices of the semiconductor device portion 210. As illustrated in FIG. 8, the wiring 221a for transferring the ground voltage GND or the power supply voltage VDD may be connected to the body 420 of the heat radiation member 400′ through the via 222 and another wiring 221b. Alternatively, if the body 420 of the heat radiation member 400′ is formed of a material the same as the material used to form the wiring 221b of the wiring portion 220, the body 420 of the heat radiation member 400′ may extend to a portion of the circuit region 200, and may be connected through the via 222 to the wiring 221a of the ground voltage GND or the power supply voltage VDD.

As described above, in the semiconductor chip 1000 according to the current embodiment, since the heat radiation member 400′ is connected to the wiring 221a of the ground voltage GND or the power supply voltage VDD, heat generated by integrated circuits may be more rapidly transferred to the heat radiation member 400′ so as to be radiated.

FIGS. 9A and 9B are plan views of a wiring layer of a semiconductor chip, according to example embodiments. Referring to FIG. 9A, the wiring layer includes a wiring region 10 and a dummy portion 20. The wiring region 10 is a region on which one or more wirings are formed to electrically connect semiconductor devices formed on the semiconductor chip, or to electrically connect voltages or signals to the semiconductor devices. In this case, the wirings are formed of a conductive material, for example, a material including a metallic material.

For uniformity of the wiring layer, the dummy portion 20 may be formed on a region other than the wiring region 10. The dummy portion 20 may be formed of a material the same as the material used to form the wirings formed on the wiring region 10. As illustrated in FIG. 9A, the dummy portion 20 may be spaced apart from the wiring region 10, and may be integrally formed on a region other than the wiring region 10. Alternatively, as illustrated in FIG. 9B, a dummy portion 20′ may be formed in the form of a plurality of lines 21 on the region other than the wiring region 10. The structure illustrated in FIG. 9A or 9B may be applied to at least one of a plurality of wiring layers of a wiring portion.

In general, a dummy portion is formed in the form of a plurality of small rectangles on a region other than a wiring region. However, if the dummy portion 20 or 20′ is formed on the whole region other than the wiring region 10 of the wiring layer integrally (see FIG. 9A) or in the form of a plurality of lines (see FIG. 9B), the dummy portion 20 or 20′ may have a larger area. However, portions of the dummy portion 20 or 20′ where signal interference possibly occurs may be formed in the form of small rectangles.

As described above, the dummy portion 20 or 20′ is formed of a metallic material the same as the metallic material used to form the wirings formed on the wiring region 10. In general, a metallic material has a relatively high thermal conductivity. Accordingly, if the dummy portion 20 or 20′ is formed on a larger area, uniformity of the wiring layer may be improved and heat radiation characteristics from the wiring layer may also be improved.

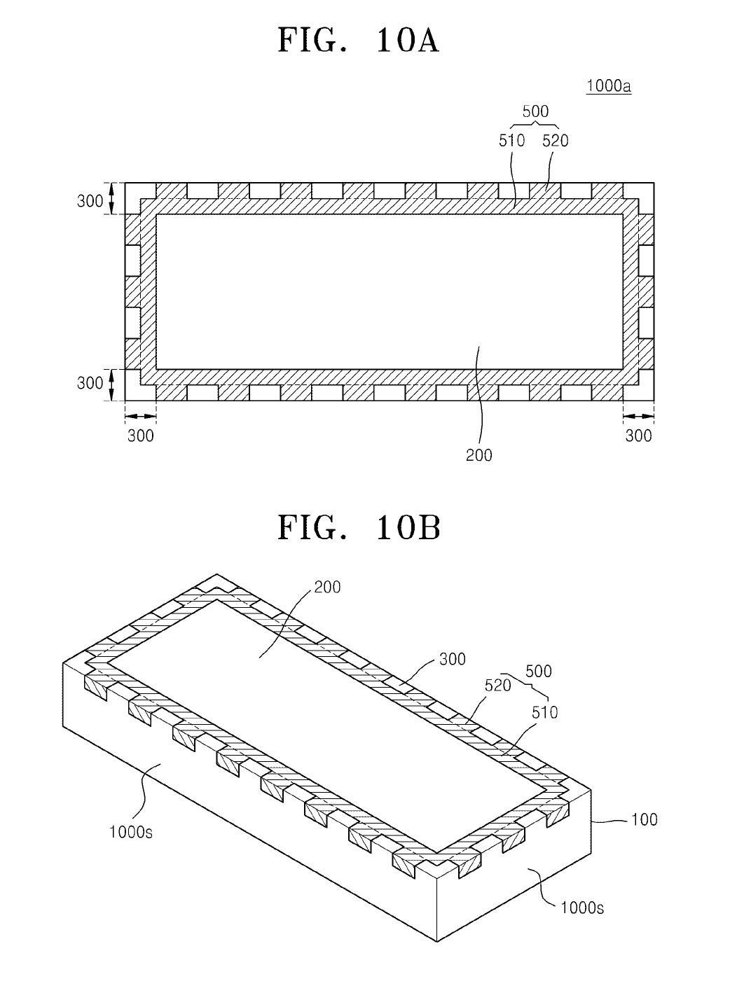

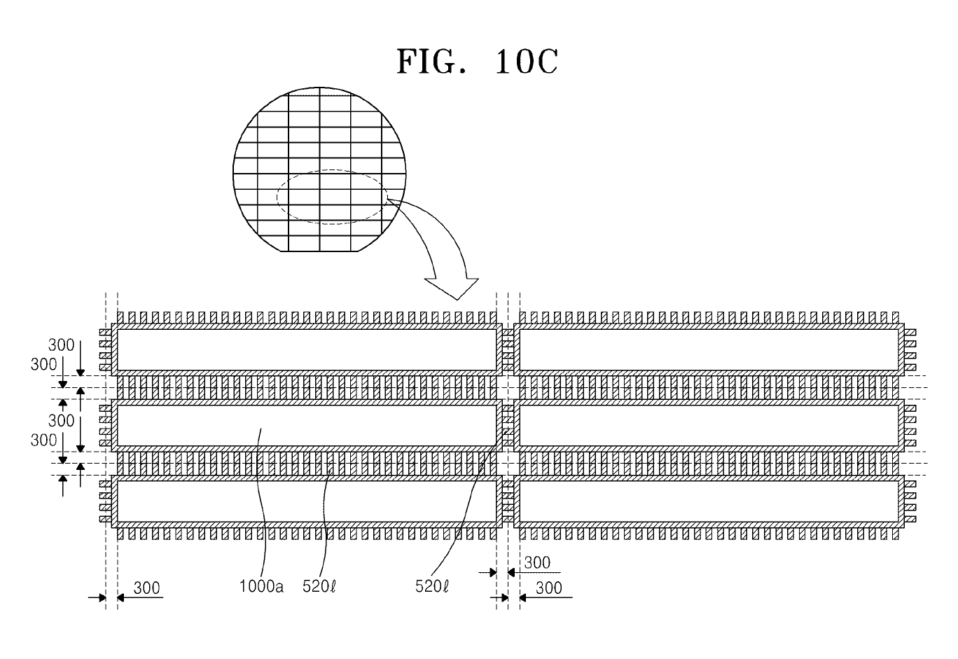

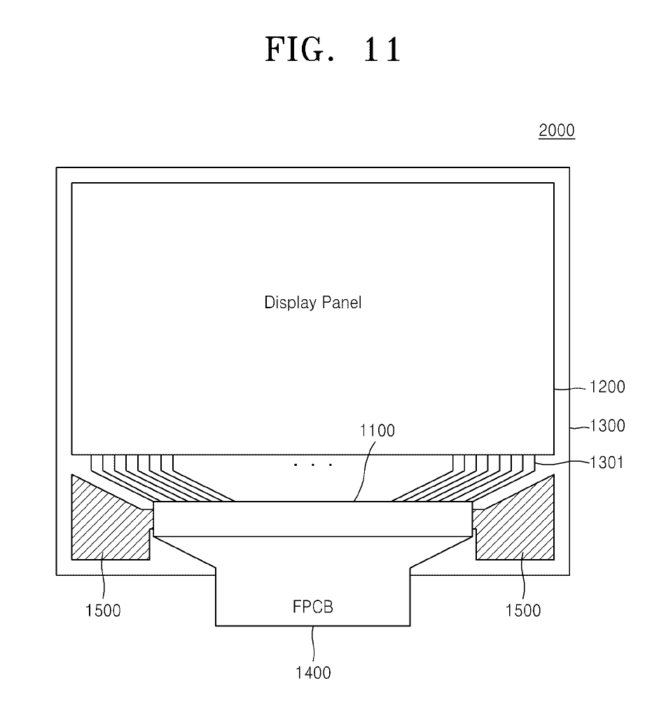

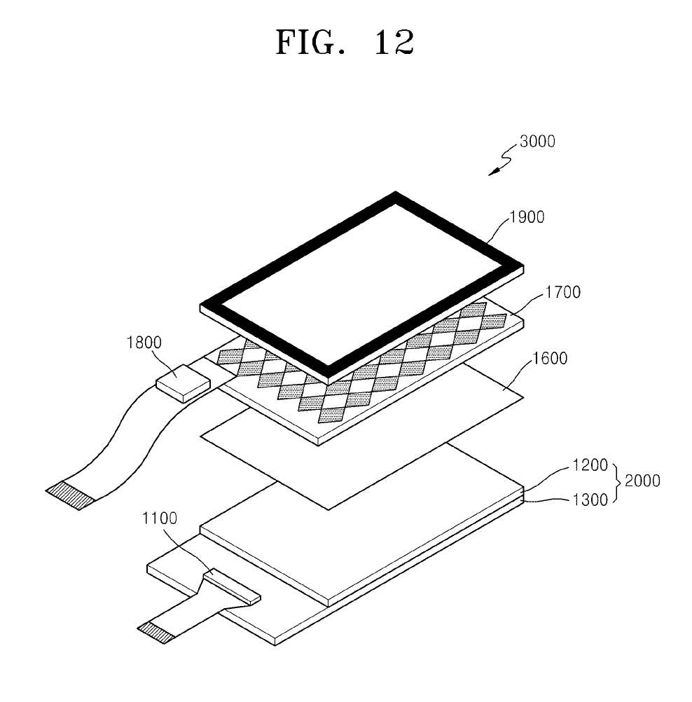

FIGS. 10A through 10C illustrate a semiconductor chip 1000a according to another example embodiment. FIG. 10A is a plan view of the semiconductor chip 1000a, FIG. 10B is a perspective view of the semiconductor chip 1000a, and FIG. 10C is a plan view of a plurality of the semiconductor chips 1000a patterned on a wafer.

Referring to FIGS. 10A and 10B, the semiconductor chip 1000a includes the circuit region 200 and a heat radiation portion 500. The heat radiation portion 500 may be formed on at least a portion of the groove (or, alternatively scribe lane region) 300 that at least partially surrounds the circuit region 200. The heat radiation portion 500 may include a body 510 and a plurality of protrusions 520. The body 510 may at least partially surround the circuit region 200, and the protrusions 520 may extend from the body 510 to side surfaces 1000s of the semiconductor chip 1000a. The heat radiation portion 500 may be a heat radiation plate having a given (or alternatively, predetermined) thickness and formed of a conductive material, for example, a metallic material such as W, Al, or Cu. A passivation layer may not be formed on the heat radiation portion 500 and thus an upper surface of the heat radiation portion 500 may be exposed externally. Also, as illustrated in FIG. 10B, vertical cross-sections of the protrusions 520 of the heat radiation portion 500 may be exposed externally on the side surfaces 1000s of the semiconductor substrate 100 of the semiconductor chip 1000a.

Referring to FIG. 10C, when a plurality of the semiconductor chips 1000a are formed on the wafer, a plurality of lines 520l having a given (or alternatively, predetermined) width may be patterned and spaced apart from each other on the groove (or, alternatively scribe lane region) 300 between the semiconductor chips 1000a in a direction perpendicular to the semiconductor chips 1000a. In this case, if the wafer is cut to individually separate the semiconductor chips 1000a, as illustrated in FIG. 10B, the heat radiation portion 500 including the protrusions 520 of which vertical cross-sections are exposed externally may be formed.

As described above, since vertical cross-sections of the protrusions 520 as well as an upper surface of the heat radiation portion 500 are exposed externally, a heat radiation area contacting air may be increased. Accordingly, the semiconductor chip 1000a may efficiently radiate heat generated from the inside of the semiconductor chip 1000a to the outside of the semiconductor chip 1000a. Also, since the heat radiation portion 500 is formed on the groove (or, alternatively scribe lane region) 300, the heat radiation portion 500 may be formed without increasing a chip size.

FIG. 11 is a schematic view of a display module 2000 according to an example embodiment. Referring to FIG. 11, the display module 2000 may include a display panel 1200, a display driving chip 1100, and a printed circuit board (PCB) 1300. Also, the display module 2000 may further include a flexible PCB (FPCB) 1400.

The display panel 1200 includes a plurality of pixel cells for displaying an image. The display panel 1200 may be an organic light radiating diode (OLED) panel. The display panel 1200 includes an OLED in which a plurality of pixels are aligned and each pixel radiates light in correspondence with current. However, the current embodiment is not limited thereto and the display panel 1200 may include various display devices. For example, the display panel 1200 may include a liquid crystal display (LCD), an electrochromic display (ECD), a digital mirror device (DMD), an actuated mirror device (AMD), a grating light valve (GLV), a plasma display panel (PDP), an electroluminescent display (ELD), a light emitting diode (LED), or a vacuum fluorescent display (VFD).

The display driving chip 1100 generates a signal for driving the display panel 1200 and transmits the signal to the display panel 1200. The display driving chip 1100 may include a voltage generator, a data driver, a scan driver, and a timing controller. The display driving chip 1100 may be a semiconductor chip including the heat radiation member 400 illustrated in FIG. 1 or the heat radiation portion 500 illustrated in FIG. 10A. Accordingly, the display driving chip 1100 may efficiently radiate heat generated when circuits operate to the outside of the display driving chip 1100.

The display driving chip 1100 is mounted on the PCB 1300. A plurality of wirings 1301 for electrically connecting the display driving chip 1100 and the display panel 1200 are formed on the PCB 1300. The PCB 1300 may be the same as a lower substrate of the display panel 1200. For example, the PCB 1300 may be a glass substrate that is a lower substrate of the display panel 1200, and the wirings 1301 for connecting the display driving chip 1100 and the display panel 1200 may be indium tin oxide (ITO) wirings.

The PCB 1300 may include a heat radiation plate 1500 formed apart from a region where the display driving chip 1100 is mounted and a region where the wirings 1301 are formed. As illustrated in FIG. 11, the display driving chip 1100 may be mounted on the PCB 1300, the wirings 1301 for electrically connecting output pads of the display driving chip 1100 and the display panel 1200 may be formed between the display driving chip 1100 and the panel 1200, and the FPCB 1400 may be disposed under the display driving chip 1100 so as to be connected to input pads of the display driving chip 1100. The heat radiation plate 1500 may be formed at two sides of the display driving chip 1100. The heat radiation plate 1500 may be formed of a metallic material. For example, the heat radiation plate 1500 may be formed of a metallic material such as W, Cu, gold (Au), silver (Ag), or Al, or a mixed material including the metallic material. As illustrated in FIG. 11, one side surface of the heat radiation plate 1500 may contact a side surface of the display driving chip 1100 or may be connected to a ground voltage pad or a power supply voltage pad of the display driving chip 1100. Accordingly, heat generated by the display driving chip 1100 may be radiated through the heat radiation plate 1500.

Although the display module 2000 includes a single display driving chip 1100 for driving the display panel 1200 in FIG. 11, the current embodiment is not limited thereto. The display module 2000 may include a plurality of display driving chips 1100, and a plurality of heat radiation plates 1500 may be formed on extra spaces at two sides of the display driving chips 1100 on the PCB 1300.

FIG. 12 is a perspective view of a display apparatus 3000 according to an example embodiment. The display apparatus 3000 may include the PCB 1300, the display driving chip 1100, the display panel 1200, a polarization plate 1600, and a window glass 1900.

The window glass 1900 is generally formed of a material such as acryl or tempered glass, and protects the display module 2000 from external impact or scratches due to repeated touch. The polarization plate 1600 may be used to improve optical characteristics of the display panel 1200. The display panel 1200 is formed by patterning a transparent electrode on the PCB 1300. The display driving chip 1100 may be mounted on the PCB 1300. For example, the PCB 1300 may be a glass substrate and the display driving chip 1100 may be mounted in the form of chip on glass (COG). However, the current embodiment is not limited thereto and the display driving chip 1100 may be mounted in various forms, for example, in the form of chip on film (COF) or chip on board (COB). The display driving chip 1100 may be a semiconductor chip including a heat radiation member or a heat radiation portion. Also, the heat radiation plate 1500 illustrated in FIG. 11 may be formed on the PCB 1300.

The display apparatus 3000 may further include a touch panel 1700 and a touch controller 1800. The touch panel 1700 may be formed by patterning a transparent electrode by using a material such as ITO on a glass substrate or a polyethylene terephthalate (PET) film. The touch controller 1800 senses a touch on the touch panel 1700, calculates a touch coordinate, and transmits the calculated coordinate to a host (not shown). The touch controller 1800 may be integrated with the display driving chip 1100 as one semiconductor chip.

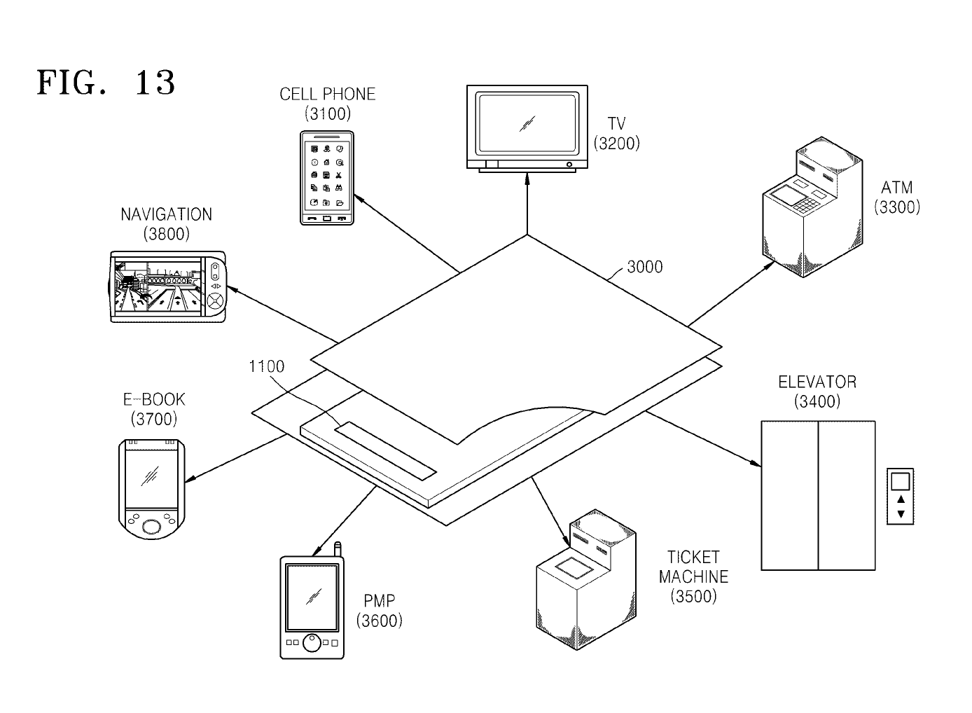

FIG. 13 is a schematic view showing various electronic products including the display apparatus 3000 illustrated in FIG. 12, according to example embodiments. The display apparatus 3000 may be used in various electronic products. The display apparatus 3000 may be used in a cell phone 3100, a TV 3200, an automatic teller machine (ATM) 3300, an elevator 3400, a ticket machine 3500 used at places such as subway stations, a portable multimedia player (PMP) 3600, an e-book 3700, and a navigation system 3800.

The inventive concepts have been particularly shown and described with reference to example embodiments thereof. Terms used herein to describe the inventive concepts are for descriptive purposes only and are not intended to limit the scope of the inventive concepts. Accordingly, it will be understood by one of ordinary skill in the art that various changes in form and details may be made therein without departing from the spirit and scope of the following claims.

What is claimed is:

1. A semiconductor chip comprising:
a circuit region on a semiconductor substrate, the circuit region having an integrated semiconductor circuit; and
a heat radiation member on at least a portion of a scribe lane region configured to at least partially surround the circuit region, the heat radiation member including a plurality of heat radiation fins that extend in a direction orthogonal to an upper surface of the semiconductor substrate.

2. The semiconductor chip of claim 1, wherein the plurality of heat radiation fins have a plate shape.

3. The semiconductor chip of claim 1, wherein the plurality of heat radiation fins have a pole shape.

4. The semiconductor chip of claim 1, wherein the plurality of heat radiation fins have different heights.

5. The semiconductor chip of claim 1, wherein the plurality of heat radiation fins include a plurality of plate-shaped heat radiation fins sequentially spaced apart from each other on the upper surface of the semiconductor substrate in a direction that is one of perpendicular and parallel to a side surface of the semiconductor chip.

6. The semiconductor chip of claim 1, wherein the heat radiation member includes a plurality of pole-shaped heat radiation fins sequentially spaced apart from each other on the upper surface of the semiconductor substrate in a direction that is one of perpendicular and parallel to a side surface of the semiconductor chip.

7. The semiconductor chip of claim 1, wherein the heat radiation member further comprises a body on the semiconductor substrate, and the body is connected to the plurality of heat radiation fins.

8. The semiconductor chip of claim 1, wherein the heat radiation member is connected to one of a power supply voltage wiring and a ground voltage wiring of the semiconductor circuit on the circuit region.

9. The semiconductor chip of claim 1, wherein the heat radiation member is exposed by an opening.

10. The semiconductor chip of claim 1, wherein the heat radiation member includes a plurality of metal layers and a plurality of vias that are alternately stacked.

11. The semiconductor chip of claim 1, further comprising:
a plurality of wiring layers on the circuit region,
wherein at least one wiring layer of the plurality of wiring layers includes a wiring region having wirings of the integrated semiconductor circuit formed thereon, and a dummy portion on a region other than the wiring region, and
wherein the dummy portion is integrally formed on a region separate from the wiring region.

12. A display module comprising:
a display panel including a plurality of pixel cells;
a display driving chip configured to drive the plurality of pixel cells, the display driving chip including a scribe lane region;
a heat radiation member on at least a portion of the scribe lane region of the display driving chip; and
a printed circuit board (PCB) having the display driving chip mounted thereon, the PCB including wirings configured to electrically connect the display driving chip and the display panel.

13. The display module of claim 12, wherein the PCB includes a heat radiation plate formed separate from a region where the display driving chip is mounted and a region where the wirings are formed, and
wherein a side surface of the heat radiation plate is configured to contact a side surface of the display driving chip.

14. The display module of claim 13, wherein the heat radiation plate is configured to electrically connect to one of a power supply voltage pad and a ground voltage pad of the display driving chip.

15. The display module of claim 14, wherein the PCB is a glass substrate.

16. A semiconductor chip comprising:
a semiconductor substrate defining a groove that at least partially surrounds an integrated circuit region; and
a heat radiation member in at least a portion of the groove, the heat radiation member including a conductive material.

17. The semiconductor chip of claim 16, wherein the conductive material includes a metallic material.

18. The semiconductor chip of claim 17, wherein the metal of the metallic material is one of copper (Cu), aluminum (Al), and tungsten (W).

19. The semiconductor chip of claim 16, wherein the heat radiation member includes a plurality of heat radiation fins that extend in a direction orthogonal to an upper surface of the semiconductor substrate.

20. The semiconductor chip of claim 19, wherein the plurality of heat radiation fins are exposed.
